(19) United States
(12) Patent Application Publication
(10) Pub. No.: US 2010/0155811 A1
(43) Pub. Date: Jun. 24, 2010

(54) SEMICONDUCTOR DEVICE, METHOD OF FABRICATING THE SAME AND FLASH MEMORY DEVICE

(76) Inventor: Sung-Joong Joo, Yongin-si (KR)

Correspondence Address: SHERR & VAUGHN, PLLC, 620 HERNDON PARKWAY, SUITE 320, HERNDON, VA, 20170, US

(21) Appl. No.: 12/641,978

(22) Filed: Dec. 18, 2009

(30) Foreign Application Priority Data
Dec. 22, 2008 (KR) 10-2008-0130809

(51) Int. Cl. H01L 29/788; H01L 29/78; H01L 21/336

(52) U.S. Cl. 257/316; 257/327; 438/259; 257/E21.422; 257/E29.302; 257/E29.256

(57) ABSTRACT

A semiconductor device includes a semiconductor substrate, a gate formed over the semiconductor substrate, a source region formed in the semiconductor substrate at one side of the gate, a drain region formed in the semiconductor substrate at another side of the gate, and a channel region formed between the source region and the drain region, the channel region including a first channel region having a first threshold voltage and a second channel region having a second threshold voltage higher than the first threshold voltage. Accordingly, the semiconductor device has two channel regions having different threshold voltages.

The present application claims priority under 35 U.S.C. §119 to Korean Patent Application No. 10-2008-0130809 (filed on Dec. 22, 2008), which is hereby incorporated by reference in its entirety.

### BACKGROUND

With the development of an information processing technology, high-integrated flash memory devices have been developed. In particular, flash memory devices having a SONOS structure have been developed. As the integration of the flash memory devices increases, a length of a channel regions becomes shorter and the efficiency of programming and erasing is reduced.

### SUMMARY

Embodiments relate to a semiconductor device that supplements a short length of a channel region and enhances characteristics of devices, a method of fabricating the same, and a flash memory device.

In accordance with embodiments, a semiconductor device can include at least one of the following: a semiconductor substrate; a gate formed on and/or over the semiconductor substrate; a source region formed on and/or over a sidewall of the gate; a drain region formed on the other side of the gate; and a channel region formed between the source region and the drain region, the channel region including a first channel region having a first threshold voltage and a second channel region having a second threshold voltage higher than the first threshold voltage.

In accordance with embodiments, a semiconductor device can include at least one of the following: a semiconductor substrate; a gate formed over the semiconductor substrate; a source region formed in the semiconductor substrate at one side of the gate; a drain region formed in the semiconductor substrate at another side of the gate; and a channel region formed between the source region and the drain region, the channel region including a first channel region having a first threshold voltage and a second channel region having a second threshold voltage higher than the first threshold voltage.

In accordance with embodiments, a method of fabricating a semiconductor device can include at least one of the following: forming a low threshold voltage region by implanting second conductive type impurities into a first conductive type semiconductor substrate; forming a high threshold voltage region by implanting second conductive type impurities having a concentration higher than the low threshold voltage region into a region adjacent to the low threshold voltage region; forming a gate on and/or over a border between the low threshold voltage region and the high threshold voltage region; and then forming a source region and a drain region at both sides of the gate.

In accordance with embodiments, a method of fabricating a semiconductor device can include at least one of the following: forming a low threshold voltage region by implanting second conductive type impurities in a first conductive type semiconductor substrate at a first concentration; forming a high threshold voltage region adjacent to the low threshold voltage region by implanting second conductive type impurities at a second concentration greater than the concentration of second conductive type impurities in the low threshold voltage region in the first conductive type semiconductor substrate; forming a gate on the first conductive type semiconductor substrate at a border between the low threshold voltage region and the high threshold voltage region; and then forming a source region and a drain region in the first conductive type semiconductor substrate at both sides of the gate.

In accordance with embodiments, a flash memory device can include at least one of the following: a first conductive type semiconductor substrate; a floating gate formed on and/or over the semiconductor substrate; a control gate formed on and/or over the floating gate; a source region formed at a side of the floating gate; a drain region formed at another side of the floating gate; and a channel region formed between the source region and the drain region, the channel region including a first channel region that is adjacent to the source region and having a first threshold voltage and a second channel region having a second threshold voltage higher than the first threshold voltage.

In accordance with embodiments, a semiconductor device can include at least one of the following: a semiconductor substrate; a floating gate formed over the semiconductor substrate; a control gate formed over the floating gate; a source region formed in the semiconductor substrate at one side of the floating gate; a drain region formed in the semiconductor substrate at a second side of the floating gate; and a channel region formed in the semiconductor substrate between the source region and the drain region, the channel region including a first channel region having a first threshold voltage formed adjacent to the source region, and a second channel region formed adjacent to the drain region having a second threshold voltage higher than the first threshold voltage.

The semiconductor device in accordance with embodiments includes a channel region having other portions such as a region into which the impurity is implanted at different concentration. Therefore, the amount of current flowing into the channel region can be changed according to the position and the characteristics of the semiconductor device can be enhanced.

A groove may be formed in the semiconductor substrate to have a structure such that the channel region has a bent cross-section, and thus, the semiconductor device in accordance with embodiments may have a high breakdown voltage drain source substrate (BVdss).

The channel region in accordance with embodiments may have a high threshold voltage at a portion adjacent to the drain region and a low threshold voltage at a portion adjacent to the source region. Accordingly, the flash memory device in accordance with embodiments can increase erasing and programming speeds, respectively.

### DRAWINGS

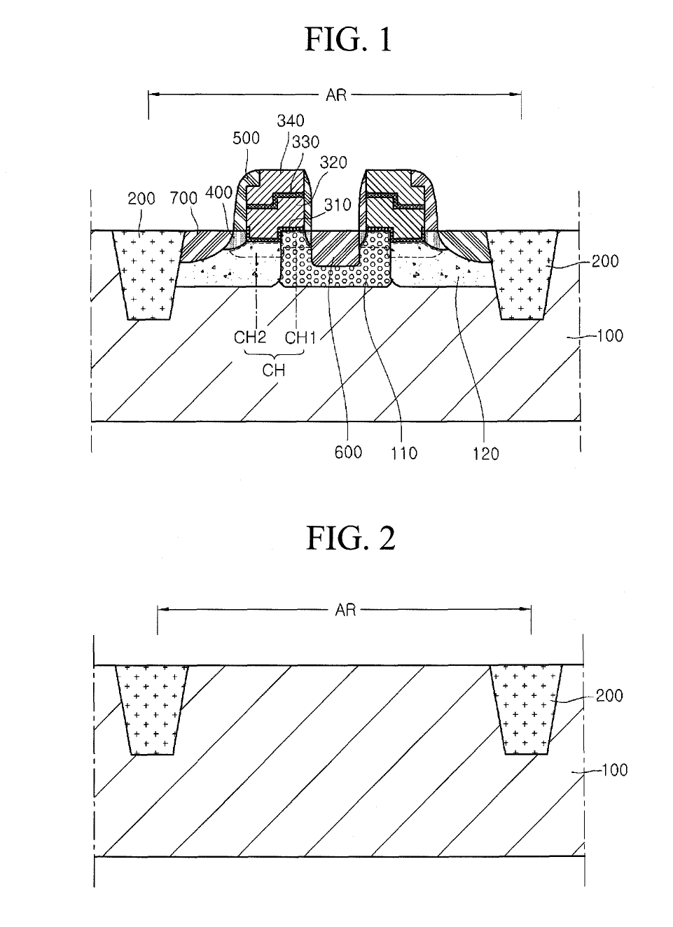

Example FIGS. 1 to 7 illustrate a flash memory device and a method of fabricating a flash memory device, in accordance with embodiments.

### DESCRIPTION

In the description of embodiments, it will be understood that when each of the substrate, film, region, groove, etc., is referred to as being formed “on” or under each of the substrate, film, electrode, region, groove, etc., the “on” and “under” includes ones that are “directly” formed or indirectly formed via other components. A reference to “on” or “under” of each component will be described with reference to the drawings. The size of each component can be exaggerated in the drawings. Further, it should be understood that the size of each component does not completely represent the actual size.

Example FIG. 1 is a cross-sectional view illustrating a flash memory device in accordance with embodiments.

As illustrated in FIG. 1, the flash memory device in accordance with embodiments includes semiconductor substrate 100, device isolating layer 200, tunnel oxide 310, floating gate 320, ONO layer 330, control gate 340, source region 600 and drain region 700.

The semiconductor substrate 100 is a p type semiconductor substrate 100. An active region (AR) is defined in the semiconductor substrate 100 by device isolating layer 200. Semiconductor substrate 100 includes low cell Vt implant region 110 and high cell Vt implant region 120. The low cell Vt implant region 110 is formed by implanting low-concentration n type impurities therein. The low cell Vt implant region 110 is formed at a middle portion of the active region (AR). The high cell Vt implant region 120 is formed by implanting low-concentration n type impurities therein. The high cell Vt implant region 120 is formed by implanting higher concentration n type impurities than the low cell Vt implant region 110 thereinto.

A groove is formed in the semiconductor substrate 100. The groove may be formed in the high cell Vt implant region 120. A groove may be formed in the low cell Vt implant region 110 at a border portion between low cell Vt implant region 110 and high cell Vt implant region 120 to thereby form a step difference therebetween.

The device isolating layer 200 is formed on the semiconductor substrate 100 and defines the active region (AR). The device isolating layer 200 is formed by an STI process and can be formed of an insulating material. The tunnel oxides 310 is formed on and/or over the semiconductor substrate 100 including the groove, low cell Vt implant region 110 and high cell Vt implant region 120. The tunnel oxide 310 can be composed of an insulating material.

The floating gate 320 is formed on and/or over the tunnel oxide 310. The tunnel oxide 310 is interposed between the floating gate 320 and the semiconductor substrate 100 to insulate the floating gate 320. The floating gate 320 is disposed at a border portion between the low cell Vt implant region 110 and the high cell Vt implant region 120. The floating gate 320 is a conductor and materials used as the floating gate 320 may include, for example, metals, polysilicon, etc. A portion of the floating gate 320 is formed to fill the groove while another portion is formed on a non-grooved surface of the semiconductor substrate 100 such that the floating gate 320 has a step difference.

The ONO layer 330 is formed on and/or over the floating gate 320. The ONO layer 330 is a multi-layer such as an oxide layer-nitride layer-oxide layer and is interposed between the floating gate 320 and the control gate 340, thereby insulating between floating gate 320 and control gate 340. The control gate 340 is formed on and/or over the ONO layer 330. The control gate 340 may have a step difference corresponding to a shape of the floating gate 320.

Spacers 500 are formed on and/or over the sidewalls of the floating gate 320 and the control gate 340. Spacers 500 include a nitride layer and/or an oxide layer for insulating the sidewalls of the floating gate 320 and the control gate 340.

The source region 600 is formed at one side of the floating gate 320. The source region 600 is formed by implanting high-concentration n type impurities therein. In accordance with embodiments, the source region 600 can be formed between two floating gates 320. The drain region 700 is formed at another side of the floating gate 320. The drain region 700 is formed by implanting high-concentration n type impurities therein. The drain region 700 can be formed at other sides of two floating gates 320, respectively. The flash memory device in accordance with embodiments includes LDD regions 400 formed adjacent to the source region 600 and the drain region 700 and below the spacer 500.

The channel region (CH) is formed below the floating gate 320 and between the source region 600 and the drain region 700. The channel region (CH) has a step difference under the groove. Moreover, the channel region (CH) is formed on and/or over the low cell Vt implant region 110 and the high cell Vt implant region 120. Therefore, the channel region (CH) is divided into a first channel region (CH1) and a second channel region (CH2). The first channel region (CH1) is formed in the low cell Vt implant region 110 and the first channel region (CH1) is adjacent to the source region 600. Moreover, the first channel region (CH1) has low threshold voltage. The second channel region (CH2) is formed in the high cell Vt implant region 120 and is adjacent to the drain region 700. Further, the second channel region CH2 has high threshold voltage. Because the channel region (CH) has a bent-shaped cross-section formed by the step difference at the groove, it has a high BVdss.

Since the first channel region (CH1) adjacent to the source region 600 has the low threshold voltage and the second channel region (CH2) adjacent to the drain region 700 has the high threshold voltage, a large amount of current may flow into the first channel region (CH1) and a relatively lower amount of current may flow into the second channel region (CH2). Therefore, the flash memory device in accordance with embodiment has a rapid erasing speed and programming speed, respectively.

Example FIGS. 2 to 7 are cross-sectional views illustrating a method of fabricating a flash memory device in accordance with embodiments.

As illustrated in example FIG. 2, a device isolating layer 200 is formed in the p type semiconductor substrate 100 to thereby define active region (AR).

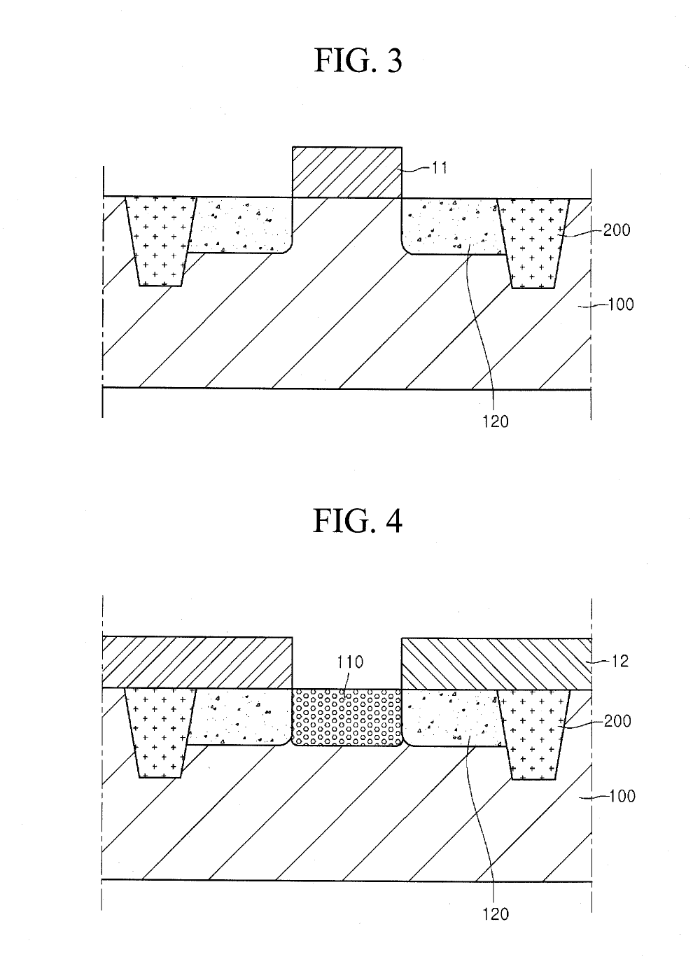

As illustrated in example FIG. 3, a first photoresist pattern 11 is formed 12 is formed on and/or over the semiconductor substrate 100 in the active region (AR) and n type impurities are selectively implanted into the semiconductor substrate 100, thereby forming the high cell Vt implant region 120.

As illustrated in example FIG. 4, a second photoresist pattern 12 is formed on and/or over the semiconductor substrate 100 and n type impurities are implanted in the semiconductor substrate 100, thereby forming the low cell Vt implant region 110. The low cell Vt implant region 110 is formed by implanting n type impurities into a region where the high cell Vt implant region 120 is not formed. The n type impurity concentration for forming the high cell Vt implant region 120 is higher than the n type impurity concentration for forming the low cell Vt implant region 110.

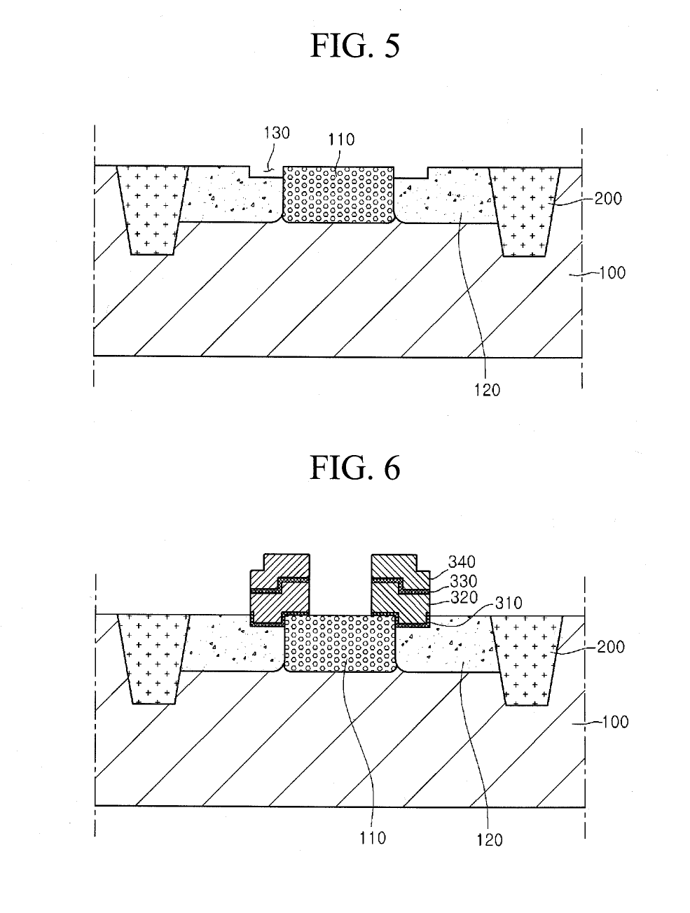

As illustrated in example FIG. 5, a groove 130 is formed in the semiconductor substrate 100. The groove 130 may be formed in the low cell Vt implant region 110 and/or the high cell Vt implant region 120.

As illustrated in example FIG. 6, an oxide layer, a first silicon layer, an ONO layer, and a second silicon layer are sequentially deposited and patterned on the semiconductor substrate 100, thereby sequentially forming the tunnel oxide 310, the floating gate 320, the ONO layer 330, and the control gate 340. The floating gate 320 is formed at a border portion between the low cell Vt implant region 110 and the high cell Vt implant region 120.

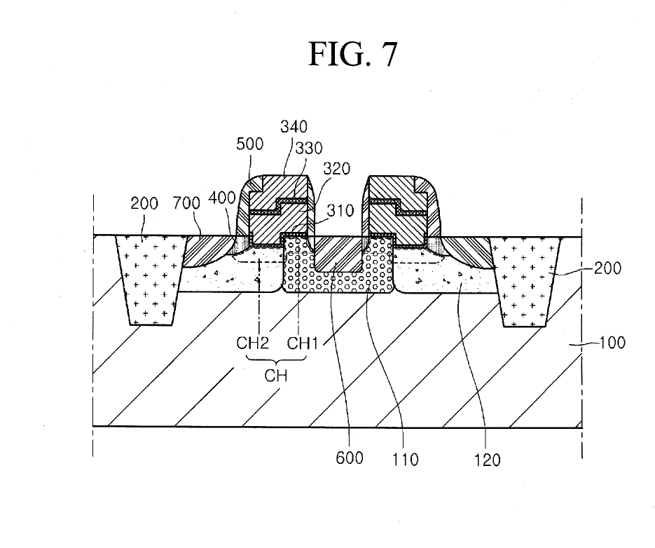

As illustrated in example FIG. 7, the low concentration n type impurities are implanted in the semiconductor substrate 100 using the control gate 340 as a mask, thereby forming an LDD region 400. Thereafter, a spacer 500 is formed on and/or over the sidewalls of the floating gate 320 and the control gate 340 and the high-concentration n type impurities is implanted into the semiconductor substrate 100 using the spacer 500 and the control gate as masks, thereby forming the source region 600 and the drain region 700. Thereby, a flash memory device is formed having the channel region which includes two regions CH1 and CH2 having different threshold voltage. Such a flash memory device in accordance with embodiments has high erasing speed and programming speed, respectively.

Although the present invention mainly describes the embodiments, this is described only by way of example but the present invention is not limited thereto. Those skilled in the art to which the present invention belongs can make several modifications and application without departing from the substantial characteristics of the embodiments. For example, each component showing in detail the embodiment can be modified and performed. The differences related to the modifications and applications can be construed to be included in the scope of the present invention that is defined in the appended claims.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a semiconductor substrate;
a gate formed over the semiconductor substrate;
a source region formed in the semiconductor substrate at one side of the gate;
a drain region formed in the semiconductor substrate at another side of the gate; and
a channel region formed between the source region and the drain region, the channel region including a first channel region having a first threshold voltage and a second channel region having a second threshold voltage higher than the first threshold voltage.

2. The apparatus of claim 1, wherein the first channel region includes impurities having a concentration less than impurities of the second channel region.

3. The apparatus of claim 1, wherein the first channel region is adjacent to the source region and the second channel region is adjacent to the drain region.

4. The apparatus of claim 1, wherein the channel region has a step difference.

5. The apparatus of claim 1, wherein the semiconductor substrate has a groove formed therein.

6. The apparatus of claim 5, wherein a portion of the gate is formed in the groove.

7. A method comprising:
forming a low threshold voltage region by implanting second conductive type impurities in a first conductive type semiconductor substrate at a first concentration;
forming a high threshold voltage region adjacent to the low threshold voltage region by implanting second conductive type impurities at a second concentration greater than the concentration of second conductive type impurities in the low threshold voltage region in the first conductive type semiconductor substrate;
forming a gate on the first conductive type semiconductor substrate at a border between the low threshold voltage region and the high threshold voltage region; and then
forming a source region and a drain region in the first conductive type semiconductor substrate at both sides of the gate.

8. The method of claim 7, further comprising forming a groove in the first conductive type semiconductor substrate.

9. The method of claim 8, wherein a portion of the gate is formed in the groove.

10. An apparatus comprising:
a semiconductor substrate;
a floating gate formed over the semiconductor substrate;
a control gate formed over the floating gate;
a source region formed in the semiconductor substrate at one side of the floating gate;
a drain region formed in the semiconductor substrate at a second side of the floating gate; and
a channel region formed in the semiconductor substrate between the source region and the drain region, the channel region including a first channel region having a first threshold voltage formed adjacent to the source region, and a second channel region formed adjacent to the drain region having a second threshold voltage higher than the first threshold voltage.

11. The apparatus of claim 10, wherein the first channel region is doped with second conductive type impurities at a first concentration.

12. The apparatus of claim 11, wherein the second channel region is doped with second conductive type impurities at second concentration.

13. The apparatus of claim 12, wherein the second concentration is greater than the first concentration.

14. The apparatus of claim 10, wherein the semiconductor substrate comprises a first conductive type semiconductor substrate.

15. The apparatus of claim 10, wherein the semiconductor substrate has a groove formed therein.

16. The apparatus of claim 15, wherein a portion of the floating gate is formed in the groove.

17. The apparatus of claim 15, wherein the floating gate comprises a first floating gate portion formed in the groove and a second floating gate portion not formed in the groove.

18. The apparatus of claim 17, wherein the floating gate has a step difference such that the uppermost surface of the first floating gate portion is below the uppermost surface of the second floating gate portion.

19. The apparatus of claim 10, further comprising a tunnel oxide layer formed over the semiconductor substrate and in the groove.

20. The apparatus of claim 19, wherein the tunnel oxide layer is formed interposed between the semiconductor substrate and the floating gate.
